(19) United States
(12) Patent Application Publication
(10) Pub. No.: US 2025/0365990 A1
(43) Pub. Date: Nov. 27, 2025

(54) MIM CAPACITOR STRUCTURE OF IMAGE SENSOR AND MANUFACTURING METHOD THEREOF

(71) Applicant: DB HiTek Co., Ltd., Bucheon-si (KR)

(72) Inventor: Chang Hun HAN, Icheon-si (KR)

(21) Appl. No.: 18/785,386

(22) Filed: Jul. 26, 2024

(30) Foreign Application Priority Data
May 27, 2024 (KR) 10-2024-0068308

(51) Int. Cl. H10D 1/00; H10D 1/68

(52) U.S. Cl. CPC H10D 1/042; H10D 1/043; H10D 1/714

(57) ABSTRACT

A MIM capacitor structure of an image sensor enables noise reduction by having increased capacitance per unit area through N capacitor structures (N>1; N=natural number) connected in parallel by forming stacked capacitors. The MIM capacitor structure of the image sensor has a first capacitor metal layer, a first intermetallic insulating film disposed on the first capacitor metal layer, a second capacitor metal layer disposed on the first intermetallic insulating film, a second intermetallic insulating film disposed on the second capacitor metal layer to cover the second capacitor metal layer, and a third capacitor metal layer disposed on the second intermetallic insulating film, wherein at least one side of the third capacitor metal layer is extending longer than a corresponding side of the second capacitor metal layer.

### CROSS REFERENCE TO RELATED APPLICATION

The present application claims priority to Korean Patent Application No. 10-2024-0068308, filed May 27, 2024, the entire contents of which are incorporated herein for all purposes by this reference.

### BACKGROUND OF THE INVENTION

### Field of the Invention

The present disclosure relates generally to a metal-insulator-metal (MIM) capacitor structure of an image sensor and a manufacturing method thereof. More particularly, the present disclosure relates to a MIM capacitor structure of an image sensor that enables noise reduction by having increased capacitance per unit area through N capacitor structures (N>1; N=natural number) connected in parallel by forming stacked capacitors, and a manufacturing method thereof.

### Description of the Related Art

An image sensor is a device that converts optical images from a subject into electrical signals. The image sensor, which is an image capturing component that generates images in a mobile phone camera, etc., may be classified into a charge coupled device (CCD) image sensor and a complementary metal oxide semiconductor (CMOS) image sensor depending on a manufacturing process and an application method. Among them, the CMOS image sensor is widely accepted in a general semiconductor chip manufacturing process due to its excellent integration competitiveness, economic efficiency, and ease of connection with peripheral chips.

An analog capacitor applied to the pixel array of the CMOS image sensor includes a metal-insulator-metal (MIM) capacitor structure. The MIM capacitor structure is mainly used in a high-performance semiconductor device because the capacitor structure has low specific resistance and no parasitic capacitance due to an internal depletion layer.

A MIM capacitor is generally formed in a structure in which electrodes and dielectric films are alternately stacked, wherein the area of each of the electrodes is designed to become smaller as the electrodes are stacked upward in order to electrically connect each of the electrodes to metal wiring through a contact, the area is designed to become narrower as the capacitors are stacked upward. Therefore, there is limitation in obtaining a desired level of capacitance due to a limited area.

### DOCUMENT OF RELATED ART

(Patent Document) Korean Patent Application Publication No. 10-2009-0022042 ‘METAL INSULATOR METAL CAPACITOR AND METHOD FOR MANUFACTURE THEREOF’

### SUMMARY OF THE INVENTION

Accordingly, the present disclosure has been made keeping in mind the above problems occurring in the related art, and the present disclosure is intended to propose a MIM capacitor structure of an image sensor that enables noise reduction by having increased capacitance per unit area through multiple capacitor structures connected in parallel by forming multiple stacked capacitors within a limited area, and a manufacturing method thereof.

In addition, the present disclosure is intended to propose a MIM capacitor structure of an image sensor that obtains increased capacitance due to an increase in the area of a fourth capacitor metal layer by positioning at least one side of the fourth capacitor metal layer on a side extending further to the outside than a corresponding side of a third capacitor metal layer, and a manufacturing method thereof.

Additionally, the present disclosure is intended to provide a MIM capacitor structure of an image sensor that allows the fourth capacitor metal layer to obtain increased capacitance together with the third capacitor metal layer through a bent portion of the fourth capacitor metal layer, and a manufacturing method thereof.

The present disclosure may be implemented through embodiments with the following configuration to achieve the purposes described above.

According to an embodiment of the present disclosure, there is provided a MIM capacitor structure of an image sensor according to the present disclosure, the structure including: a first capacitor metal layer; a first intermetallic insulating film on the first capacitor metal layer; a second capacitor metal layer on the first intermetallic insulating film; a second intermetallic insulating film located on the second capacitor metal layer to cover the second capacitor metal layer; and a third capacitor metal layer on the second intermetallic insulating film, wherein at least one side of the third capacitor metal layer is located at a side extending longer outward than a corresponding side of the second capacitor metal layer.

According to another embodiment of the present disclosure, in the MIM capacitor structure of an image sensor according to the present disclosure, the third capacitor metal layer may have a larger area than the second capacitor metal layer.

According to another embodiment of the present disclosure, in the MIM capacitor structure of an image sensor according to the present disclosure, all sides of the third capacitor metal layer may be respectively located at sides extending longer outward than corresponding sides of the second capacitor metal layer.

According to another embodiment of the present disclosure, in the MIM capacitor structure of an image sensor according to the present disclosure, the third capacitor metal layer may include a bent portion extending downward on the at least one side thereof so that the bent portion at least partially surrounds the corresponding side of the second capacitor metal layer.

According to another embodiment of the present disclosure, in the MIM capacitor structure of an image sensor according to the present disclosure, the bent portion may have a vertical length to laterally overlap the corresponding side of the second capacitor metal layer.

According to another embodiment of the present disclosure, in the MIM capacitor structure of an image sensor according to the present disclosure, the bent portion may be spaced apart from one side of the second capacitor metal layer facing the bent portion by the second intermetallic insulating film.

According to another embodiment of the present disclosure, the MIM capacitor structure of an image sensor according to the present disclosure may further include: top metal layers connected to the first capacitor metal layer, the second capacitor metal layer, and the third capacitor metal layer, respectively.

According to another embodiment of the present disclosure, there is provided a MIM capacitor structure of an image sensor according to the present disclosure, the structure including: a first capacitor metal layer; a first intermetallic insulating film on the first capacitor metal layer; a second capacitor metal layer on the first intermetallic insulating film; a second intermetallic insulating film on the second capacitor metal layer; a third capacitor metal layer on the second intermetallic insulating film; a third intermetallic insulating film located on the third capacitor metal layer to cover the third capacitor metal layer; and a fourth capacitor metal layer on the third intermetallic insulating film, wherein at least one side of the fourth capacitor metal layer is located at a side extending longer outward than a corresponding side of the third capacitor metal layer.

According to another embodiment of the present disclosure, in the MIM capacitor structure of an image sensor according to the present disclosure, the second capacitor metal layer may have a smaller width size than the first capacitor metal layer.

According to another embodiment of the present disclosure, in the MIM capacitor structure of an image sensor according to the present disclosure, the third capacitor metal layer may have a smaller width size than the second capacitor metal layer.

According to another embodiment of the present disclosure, in the MIM capacitor structure of an image sensor according to the present disclosure, at least one side of the fourth capacitor metal layer may cover one side of the third capacitor metal layer.

According to another embodiment of the present disclosure, in the MIM capacitor structure of an image sensor according to the present disclosure, the fourth capacitor metal layer may have a portion extending downward from a lower side of one side thereof and facing one side of the third capacitor metal layer adjacent thereto.

According to another embodiment of the present disclosure, in the MIM capacitor structure of an image sensor according to the present disclosure, the fourth capacitor metal layer may cover all sides of the third capacitor metal layer.

According to another embodiment of the present disclosure, the MIM capacitor structure of an image sensor according to the present disclosure may further include: multiple top metal layers spaced apart from each other above the fourth capacitor metal layer, wherein each of the capacitor metal layers may be electrically connected to each of the top metal layers by each contact.

According to another embodiment of the present disclosure, there is provided a manufacturing method of the MIM capacitor structure of an image sensor according to the present disclosure, the method including: depositing a first insulating film on a first metal layer, a second metal layer on the first insulating film, a second insulating film on the second metal layer, and a third metal layer on the second insulating film; forming a first capacitor metal layer by etching the third metal layer; depositing a third insulating film on the second insulating film to cover the first capacitor metal layer, and depositing a fourth metal layer on the third insulating film; and forming a second capacitor metal layer on the third insulating film by etching the fourth metal layer, wherein one side of the second capacitor metal layer is located at a side extending longer outward than one side of the first capacitor metal layer.

According to another embodiment of the present disclosure, in the manufacturing method of the MIM capacitor structure of an image sensor according to the present disclosure, the third insulating film may include a step.

According to another embodiment of the present disclosure, in the manufacturing method of the MIM capacitor structure of an image sensor according to the present disclosure, the second capacitor metal layer may be formed to cover one side of the first capacitor metal layer.

According to another embodiment of the present disclosure, the manufacturing method of the MIM capacitor structure of an image sensor according to the present disclosure may further include: forming a first intermetallic insulating film, a second intermetallic insulating film, and a third capacitor metal layer by etching the second insulating film, the third insulating film, and the second metal layer.

According to another embodiment of the present disclosure, the manufacturing method of the MIM capacitor structure of an image sensor according to the present disclosure may further include: forming a third intermetallic insulating film and a fourth capacitor metal layer by etching the first insulating film and the first metal layer.

According to another embodiment of the present disclosure, in the manufacturing method of the MIM capacitor structure of an image sensor according to the present disclosure, the fourth capacitor metal layer may have a larger width size than the third capacitor metal layer.

The present disclosure has the following effects due to the configuration described above.

According to the present disclosure, increased capacitance per unit area is obtained through multiple capacitor structures connected in parallel by forming multiple stacked capacitors within a limited area, thereby enabling noise reduction.

In addition, according to the present disclosure, at least one side of the fourth capacitor metal layer is positioned on a side extending further to the outside than a corresponding side of the third capacitor metal layer, thereby obtaining increased capacitance due to an increase in the area of the fourth capacitor metal layer.

In addition, according to the present disclosure, the fourth capacitor metal layer obtains increased capacitance together with the third capacitor metal layer through the bent portion of the fourth capacitor metal layer.

Meanwhile, it should be added that even if effects are not explicitly mentioned here, the effects described in the following specifications and potential effects thereof expected by the technical features of the present disclosure are treated as if they were described in the specifications of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view of a MIM capacitor structure of an image sensor according to an embodiment of the present disclosure;

FIG. 2 is a cross-sectional view taken along line AA′ of the MIM capacitor structure of an image sensor according to FIG. 1;

FIG. 3 is an equivalent circuit diagram of the MIM capacitor structure of an image sensor according to FIG. 1; and

FIGS. 4 to 13 are cross-sectional views for describing the manufacturing method of the MIM capacitor structure of an image sensor according to the embodiment of the present disclosure.

### DETAILED DESCRIPTION OF THE INVENTION

Hereinafter, embodiments of the present disclosure will be described in more detail with reference to the attached drawings. The embodiments of the present disclosure may be modified in various forms, and the scope of the present disclosure should not be construed as limited to the embodiments below and should be interpreted on the basis of the matters stated in the claims. In addition, these embodiments are only provided as a reference to more completely explain the present disclosure to those with average knowledge in the art.

Hereinafter, when a first component (or layer) is described as being placed on a second component (or layer), it should be noted that the first component may be placed directly on the second component, or there may be a third component(s) or layer(s) located between the corresponding components. Additionally, when the first component is expressed as being placed directly on or above the second component, no other component(s) are located between the corresponding components. In addition, being located on the ‘upper part’, ‘lower part’, ‘upper side’, ‘lower side’ or ‘one side’ or ‘side surface’ of the first component means a relative positional relationship.

Additionally, it should be noted that in a case in which a specific embodiment can be implemented differently, a specific process sequence may be different from a process sequence to be described below. For example, two processes described sequentially may be performed substantially at the same time or may be performed in the opposite order.

In addition, hereinafter, when explaining the components of the present disclosure, numbers are written in front of components, such as ‘first’ and ‘second’ components. However, each of the components is independent, and it should be noted that the ‘second’ component does not presuppose the ‘first’ component for example.

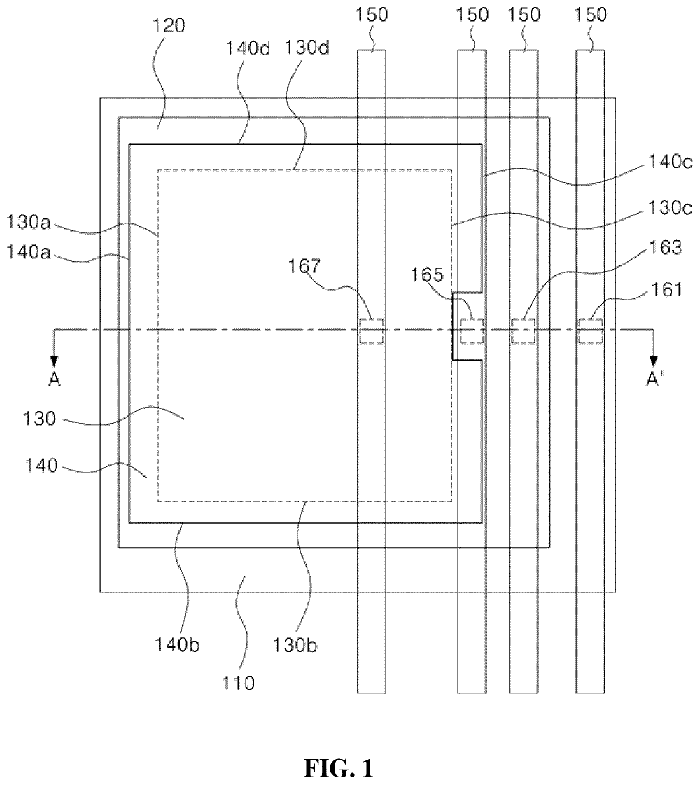

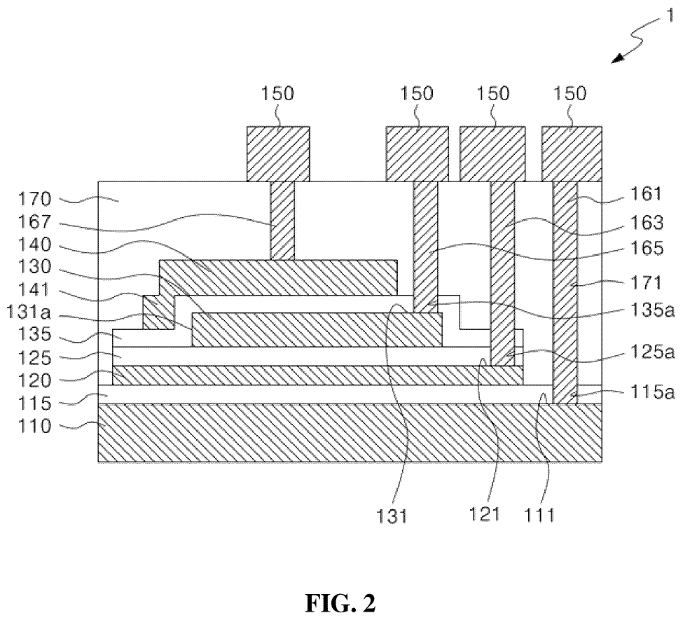

FIG. 1 is a plan view of a MIM capacitor structure of an image sensor according to an embodiment of the present disclosure; and FIG. 2 is a cross-sectional view taken along line AA′ of the MIM capacitor structure of an image sensor according to FIG. 1.

Hereinafter, a MIM capacitor structure 1 of an image sensor according to the embodiment of the present disclosure will be described in detail with reference to the accompanying drawings. The MIM capacitor structure 1 according to the present disclosure is understood to be formed in the pixel region of the image sensor rather than the logic region of the image sensor. In addition, it should be noted that although four capacitor electrodes are formed in the drawings, there is no separate limitation on the number of the capacitor electrodes formed.

Referring to FIGS. 1 and 2, the present disclosure relates generally to the metal-insulator-metal (MIM) capacitor structure 1 of an image sensor. More particularly, the present disclosure relates to the MIM capacitor structure 1 of an image sensor that enables noise reduction by having increased capacitance per unit area through N capacitor structures (N>1; N=natural number) connected in parallel by forming stacked capacitors.

The MIM capacitor structure 1 of an image sensor according to the embodiment of the present disclosure may include a first capacitor metal layer 110 as a capacitor electrode at a lowest side thereof. For example, the first capacitor metal layer 110, which is a metal layer formed of one or more of Ti/TiN/Al/Cu, may have an approximately quadrangular planar shape, but there is no separate limitation thereon. In addition, the first capacitor metal layer 110 is preferably configured to have a larger area than a second capacitor metal layer 120, a third capacitor metal layer 130, and a fourth capacitor metal layer 140, which will be described later. In particular, the first capacitor metal layer 110 may have a side connected to a first contact 161 to be electrically connected to a top metal layer 150. That is, the first capacitor metal layer 110 preferably has an open first connection portion 111 that does not overlap vertically with the second capacitor metal layer 120 so that the upper surface of the first capacitor metal layer 110 is physically connected to the lower surface of the first contact 161.

In addition, a first intermetallic insulating film 115, which is a dielectric film, may be formed on the first capacitor metal layer 110. The first intermetallic insulating film 115 is an insulating film formed between the first capacitor metal layer 110 and the second capacitor metal layer 120 and may include various insulating materials such as SiO₂, SiN, Al₂O₃, HfO₂, TiO₂ and/or TaO₅. The first intermetallic insulating film 115 may be formed to have a substantially identical area to the first capacitor metal layer 110, but the scope of the present disclosure is not limited thereto. A contact hole 115a may be formed on one side of the first intermetallic insulating film 115 so that the first contact 161 is physically connected to the first connection portion 111.

In addition, the second capacitor metal layer 120 may be formed on the first intermetallic insulating film 115. The second capacitor metal layer 120 is a metal layer formed of one or more of Ti/TiN/Al/Cu, for example, and may be formed between the first intermetallic insulating film 115 and a second intermetallic insulating film 125. In addition, the second capacitor metal layer 120 may have an approximately quadrangular planar shape, but there is no separate limitation thereon. As described above, the second capacitor metal layer 120 is preferably configured to have a smaller area than the first capacitor metal layer 110 so that the open first connection portion 111 is formed on the first capacitor metal layer 110.

In this case, the second capacitor metal layer 120 may have a side that is not at least partially covered by the third capacitor metal layer 130 above the second capacitor metal layer 120. That is, the second capacitor metal layer 120 may have an open second connection portion 121 that does not overlap vertically with the third capacitor metal layer 130. Through a second contact 163 that is physically connected to the second connection portion 121, the second capacitor metal layer 120 may be electrically connected to a top metal layer 150. In an embodiment of the present disclosure, the second capacitor metal layer 120 and the first intermetallic insulating film 115 under the second capacitor metal layer 120 may respectively include multiple second capacitor metal layers and first intermetallic insulating films alternately stacked, or may not be formed. For example, in some cases, the first intermetallic insulating film 115 and the second capacitor metal layer 120 may include a plurality of first intermetallic insulating films and a plurality of second capacitor metal layer, which are alternately formed, wherein each of the second capacitor metal layers 120 may be configured to have a different size from each other. Alternatively, for example, the second intermetallic insulating film 125 and the third capacitor metal layer 130 may be formed directly on the first capacitor metal layer 110.

The second intermetallic insulating film 125, which is a dielectric film formed on the first capacitor metal layer 110 or the second capacitor metal layer 120, may be formed on the lower surface of the third capacitor metal layer 130. The second intermetallic insulating film 125 may include various insulating materials, such as SiO₂, SiN, Al₂O₃, HfO₂, TiO₂, and/or TaO₅. In addition, a contact hole 125a may be formed on one side of the second intermetallic insulating film 125 so that the second contact 163 is physically connected to the second connection portion 121. In addition, the third capacitor metal layer 130 is formed on the second intermetallic insulating film 125, and may be a metal layer formed of one or more of Ti/TiN/Al/Cu, for example. The third capacitor metal layer 130 may be formed between the second intermetallic insulating film 125 and a third intermetallic insulating film 135.

In this case, the third capacitor metal layer 130 is preferably formed to have a smaller planar area than the fourth capacitor metal layer 140. For example, the third capacitor metal layer 130 may have at least one side 130a formed to be shorter than the corresponding side 140a of the fourth capacitor metal layer 140. For example, when both the third capacitor metal layer 130 and the fourth capacitor metal layer 140 have quadrangular planar shapes, the corresponding side 140a of the fourth capacitor metal layer 140 is preferably configured to extend further to the outside than the one side 130a of the third capacitor metal layer 130, and at least three sides 140a, 140b, and 140c of the fourth capacitor metal layer 140 are more preferably configured to be located respectively on sides extending further to the outside than the corresponding sides 130a, 130b, and 130c of the third capacitor metal layer 130. For example, the corresponding sides 140a, 140b, 140c, and 140d of the fourth capacitor metal layer 140 may be configured to be respectively located at sides extending more to the outside than all sides 130a, 130b, 130c, and 130d except for a third connection portion 131 of the third capacitor metal layer 130. In addition, the at least one side 130a of the third capacitor metal layer 130 may be at least partially surrounded by the fourth capacitor metal layer 140, and details thereof will be described later. The third connection portion 131 is an open side that does not overlap vertically with the fourth capacitor metal layer 140, and through a third contact 165 that is physically connected to the third connection portion 131, the third capacitor metal layer 130 may be electrically connected to a top metal layer 150. The above term ‘outside’ is understood to mean a side that is horizontally away from the center of the capacitor structure 1 in the plan view (FIG. 1).

In addition, the third intermetallic insulating film 135, which is a dielectric film, may be formed on the third capacitor metal layer 130. The third intermetallic insulating film 135, which is an insulating film formed between the third capacitor metal layer 130 and the fourth capacitor metal layer 140, may include various insulating materials such as SiO₂, SiN, Al₂O₃, HfO₂, TiO₂ and/or TaO₅. In addition, a contact hole 135a may be formed in one side of the third intermetallic insulating film 135 so that the third contact 165 is physically connected to the third connection portion 131.

Next, the fourth capacitor metal layer 140 may be formed on the third intermetallic insulating film 135. For example, the fourth capacitor metal layer 140 may be a metal layer formed of one or more of Ti/TiN/Al/Cu. Furthermore, the fourth capacitor metal layer 140 may have an approximately quadrangular planar shape except for a side which the third contact 165 crosses, but there is no separate limitation thereon.

The fourth capacitor metal layer 140 is preferably configured to have a larger area than the third capacitor metal layer 130. As described above, at least one side 140a of the fourth capacitor metal layer 140 may be formed to be longer than the corresponding side 130a of the third capacitor metal layer 130. In addition, the at least one side 140a of the fourth capacitor metal layer 140 is formed to be longer than the corresponding side 130a of the third capacitor metal layer 130, and may have a bent portion 141 extending downward therefrom. The third intermetallic insulating film 135 may be formed between the bent portion 141 and the side of the third capacitor metal layer 130 facing the bent portion 141. The bent portion 141 may be formed to have a length to overlap the side of the third capacitor metal layer 130 in a lateral direction. In addition, the bent portion 141 may be formed on each of all sides 140a, 140b, 140c, and 140d of the fourth capacitor metal layer 140, or may be formed only on some sides thereof, and there is no separate limitation thereon.

In addition, the fourth capacitor metal layer 140 may be electrically connected to a top metal layer 150 by a fourth contact 167. For example, the upper surface of the fourth capacitor metal layer 140 may be physically connected to the lower surface of the fourth contact 167.

In addition, the first intermetallic insulating film 115, the second capacitor metal layer 120, the second intermetallic insulating film 125, the third capacitor metal layer 130, the third intermetallic insulating film 135, and the fourth capacitor metal layer 140, which are located on the first capacitor metal layer 110, may be covered by an interlayer insulating film 170, and the top metal layers 150 may on the upper surface of the interlayer insulating film 170. In addition, the top metal layers 150 may be electrically connected to the metal layers 110, 120, 130, and 140 by the first contact 161, the second contact 163, the third contact 165, and the fourth contact 167 formed in multiple contact holes 171 formed vertically within the interlayer insulating film 170.

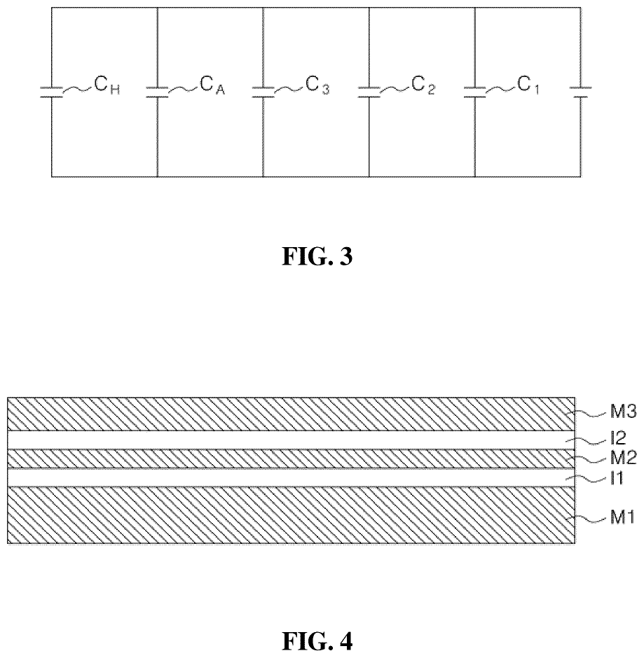

FIG. 3 is an equivalent circuit diagram of the MIM capacitor structure of an image sensor according to FIG. 1.

Referring to FIGS. 1 to 3, the MIM capacitor structure 1 according to an embodiment of the present disclosure as described above may be configured such that a second capacitor C2 including the second capacitor metal layer 120, the second intermetallic insulating film 125, and the third capacitor metal layer 130 is stacked on a first capacitor C1 including the first capacitor metal layer 110, the first intermetallic insulating film 115, and the second capacitor metal layer 120, and a third capacitor C3 including the third capacitor metal layer 130, the third intermetallic insulating film 135, and the fourth capacitor metal layer 140 is stacked on the second capacitor C2 to form the multiple capacitors connected in parallel so as to have a higher capacitance (C1+C2+C3) within a limited area (C1+C2+C3). That is, through the present disclosure, an increased capacitance value per unit area may be obtained.

In addition, in the present disclosure, by positioning the at least one side 140a of the fourth capacitor metal layer 140 on a side extending further to the outside than the corresponding side 130a of the third capacitor metal layer 130, capacitance C_{A} due to an increase in the area of the fourth capacitor metal layer 140, and additional capacitance C_{H} between the bent portion 141 and the third capacitor metal layer 130 facing the bent portion 141 are obtained, so it is possible to obtain a higher value of capacitance C1+C2+C_{A}+C_{H}. That is, in an embodiment of the present disclosure, it is possible to obtain optimal MIM capacitance in the same area.

FIGS. 4 to 13 are cross-sectional views for describing the manufacturing method of the MIM capacitor structure of an image sensor according to the embodiment of the present disclosure.

Hereinafter, the manufacturing method of the MIM capacitor structure of an image sensor according to the embodiment of the present disclosure will be described in detail with reference to the accompanying drawings.

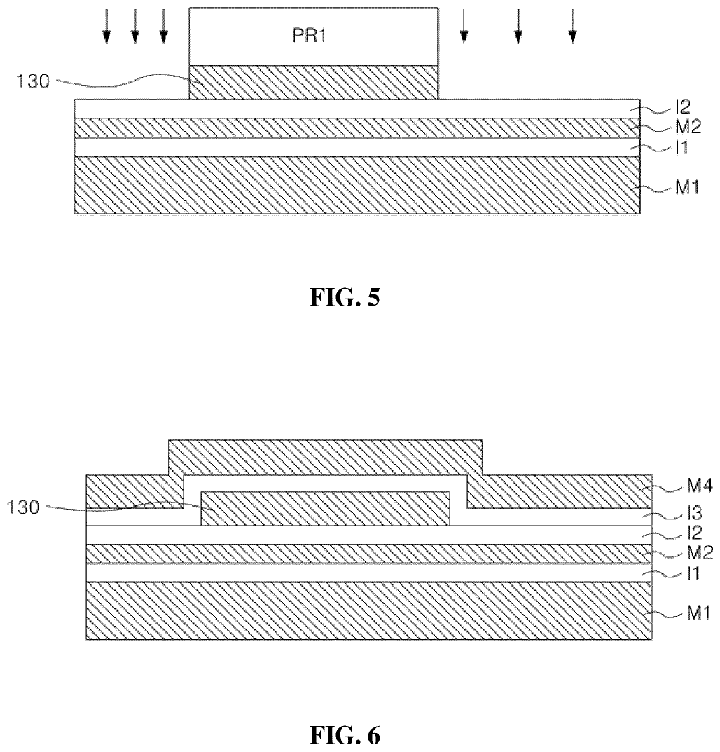

Referring to FIG. 4, first, a first metal layer M1 is deposited on an insulating film (not shown), and sequentially, a first insulating film I1 is deposited on the first metal layer M1, a second metal layer M2 is deposited on the first insulating film I1, a second insulating film 12 is deposited on the metal layer M2, and a third metal layer M3 is deposited on the second insulating film 12. Next, referring to FIG. 5, the third capacitor metal layer 130 is formed on the second insulating film 12 by etching the third metal layer M3. For example, the third capacitor metal layer 130 may be formed through an etching process by using a photoresist film PR1 formed on the third metal layer M3 as a mask pattern. Afterwards, the photoresist film PR1 may be removed by performing a strip process.

Referring to FIG. 6, after the third capacitor metal layer 130 is formed, a third insulating film 13 is deposited on the second insulating film 12 to cover the third capacitor metal layer 130, and a fourth metal layer M4 is deposited on the third insulating film 13.

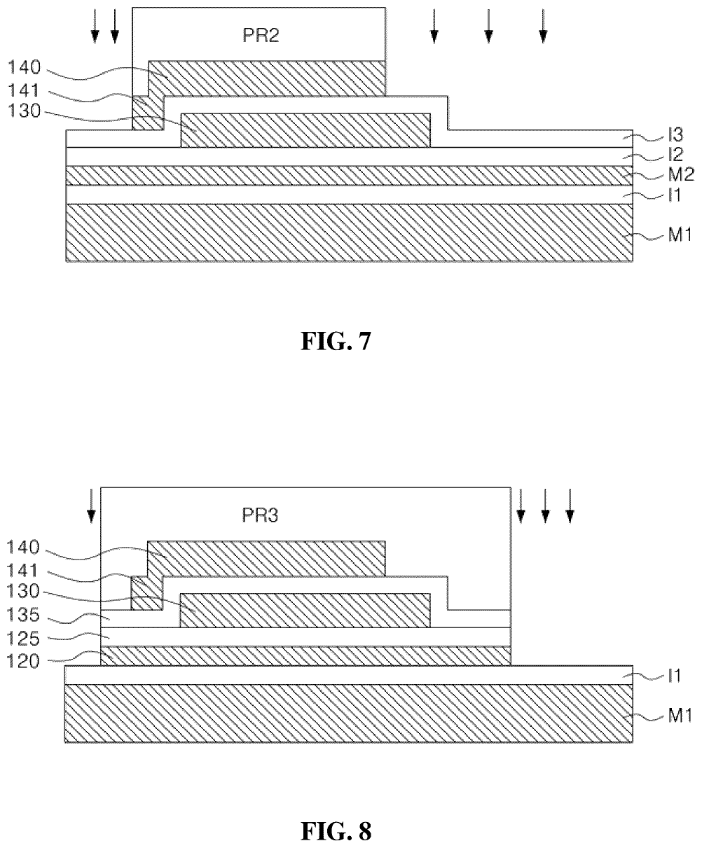

Next, referring to FIG. 7, the fourth capacitor metal layer 140 is formed on the third insulating film 13 by etching the fourth metal layer M4. For example, the fourth capacitor metal layer 140 may be formed through an etching process by using a photoresist film PR2 formed on the fourth metal layer M4 as a mask pattern. Afterwards, the photoresist film PR2 may be removed by performing a strip process.

In this case, the at least one side 140a of the fourth capacitor metal layer 140 is preferably configured to be located on a side extending further to the outside than the corresponding side 130a of the third capacitor metal layer 130. In addition, the bent portion 141 is more preferably formed on the at least one side 140a of the fourth capacitor metal layer 140 to surround the corresponding side 130a of the third capacitor metal layer 130. The bent portion 141 may be spaced a predetermined distance apart from the side of the third capacitor metal layer 130 facing the bent portion 141 by the third insulating film I3.

Referring to FIG. 8, after forming the fourth capacitor metal layer 140, the third intermetallic insulating film 135, the second intermetallic insulating film 125, and the second capacitor metal layer 120 may be sequentially formed through an etching process. For example, by using a photoresist film PR3 formed on the third insulating film 13 and the fourth capacitor metal layer 140 as a mask pattern, the third insulating film 13, the second insulating film 12, and the second metal layer M2 are sequentially etched, so that the third intermetallic insulating film 135, the second intermetallic insulating film 125, and the second capacitor metal layer 120 may be formed. Afterwards, the photoresist film PR3 may be removed by performing a strip process.

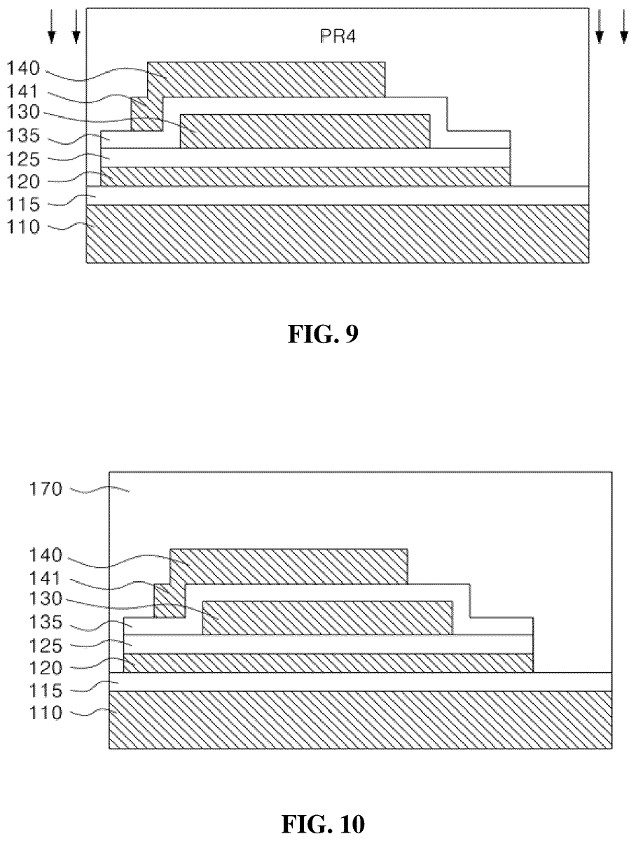

Next, referring to FIG. 9, through etching, the first intermetallic insulating film 115 and the first capacitor metal layer 110 may be formed sequentially. For example, by using a photoresist film PR4 formed on the fourth capacitor metal layer 140 and the third intermetallic insulating film 135 as a mask pattern, the first insulating film I1 and the first metal layer M1 are sequentially etched, so that the first intermetallic insulating film 115 and the first capacitor metal layer 110 may be formed.

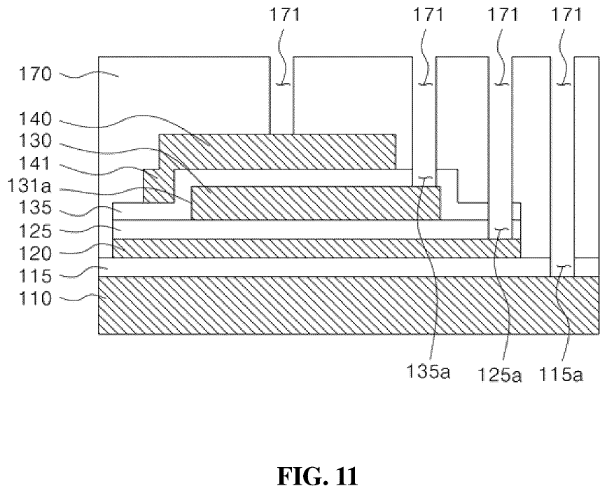

Next, referring to FIG. 10, the interlayer insulating film 170 is deposited to cover all structures on the first capacitor metal layer 110.

Referring to FIG. 11, after the interlayer insulating film 170 is formed, the contact holes 171 are formed in the interlayer insulating film 170, the contact hole 115a is formed in the first intermetallic insulating film 115, the contact hole 125a is formed in the second intermetallic insulating film 125, and the contact hole 135a is formed in the third intermetallic insulating film 135. Each of the contact holes may be formed by forming a trench through dry etching or wet etching.

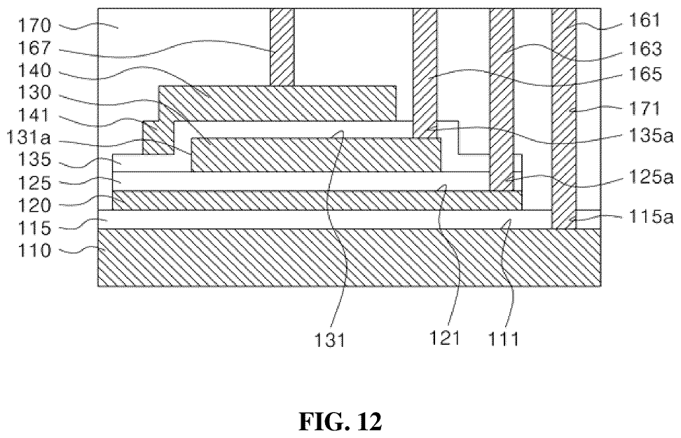

In addition, referring to FIG. 12, the contacts 161, 163, 165, and 167 are formed in the interlayer insulating film 170. For example, to fill each of the contact holes 171, 125a, and 135a, a metal layer (not shown) is formed on the interlayer insulating film 170, so that the contacts 161, 163, 165, and 167 are formed. When the contacts 161, 163, 165, and 167 are formed, the metal layer remaining on the interlayer insulating film 170 are removed.

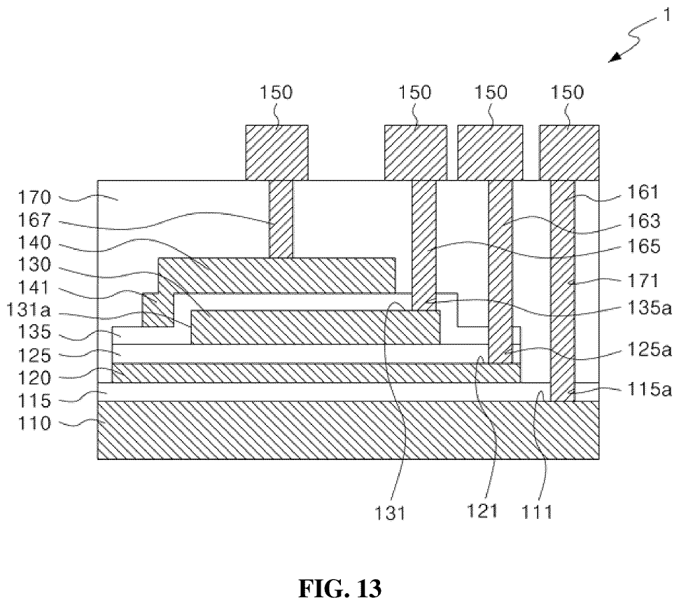

Referring to FIG. 13, finally, the top metal layers 150 may be formed on the interlayer insulating film 170. Each of the top metal layers 150 may be formed through an etching process after forming an additional metal layer (not shown) on the interlayer insulating film 170, and detailed description thereof will be omitted.

The detailed description above is illustrative of the present disclosure. Additionally, the foregoing describes preferred embodiments of the present disclosure, and the present disclosure may be used in various other combinations, modifications, and circumstances thereof. That is, changes or modifications may be made within the scope of the concept of the invention disclosed in this specification, a scope equivalent to the written disclosure, and/or the scope of technology or knowledge in the art. The above-described embodiments illustrate the best state for implementing the technical idea of the present disclosure, and various changes thereof required for specific application fields and uses of the present disclosure are also possible. Accordingly, the above detailed description of the invention is not intended to limit the present disclosure to the disclosed embodiments.

What is claimed is:

1. A MIM capacitor structure of an image sensor, the structure comprising:
a first capacitor metal layer;
a first intermetallic insulating film disposed on the first capacitor metal layer;
a second capacitor metal layer disposed on the first intermetallic insulating film;
a second intermetallic insulating film disposed on the second capacitor metal layer to cover the second capacitor metal layer; and
a third capacitor metal layer disposed on the second intermetallic insulating film,
wherein at least one side of the third capacitor metal layer is extending longer than a corresponding side of the second capacitor metal layer.

2. The MIM capacitor structure of claim 1, wherein the third capacitor metal layer has a larger area than an area of the second capacitor metal layer.

3. The MIM capacitor structure of claim 1, wherein all sides of the third capacitor metal layer are respectively extending longer than corresponding sides of the second capacitor metal layer.

4. The MIM capacitor structure of claim 1, wherein the third capacitor metal layer comprises a bent portion extending downward on the at least one side of the third capacitor metal layer so that the bent portion at least partially surrounds the corresponding side of the second capacitor metal layer.

5. The MIM capacitor structure of claim 4, wherein the bent portion has a vertical length to laterally overlap the corresponding side of the second capacitor metal layer.

6. The MIM capacitor structure of claim 4, wherein the bent portion is spaced apart from the corresponding side of the second capacitor metal layer facing the bent portion by the second intermetallic insulating film.

7. The MIM capacitor structure of claim 4, further comprising:
top metal layers connected to the first capacitor metal layer, the second capacitor metal layer, and the third capacitor metal layer, respectively.

8. A MIM capacitor structure of an image sensor, the structure comprising:
a first capacitor metal layer;
a first intermetallic insulating film disposed on the first capacitor metal layer;
a second capacitor metal layer disposed on the first intermetallic insulating film;
a second intermetallic insulating film disposed on the second capacitor metal layer;
a third capacitor metal layer disposed on the second intermetallic insulating film;
a third intermetallic insulating film disposed on the third capacitor metal layer to cover the third capacitor metal layer; and
a fourth capacitor metal layer disposed on the third intermetallic insulating film,
wherein at least one side of the fourth capacitor metal layer is extending longer than a corresponding side of the third capacitor metal layer.

9. The MIM capacitor structure of claim 8, wherein the second capacitor metal layer has a smaller width than a width of the first capacitor metal layer.

10. The MIM capacitor structure of claim 9, wherein the third capacitor metal layer has a smaller width than a width of the second capacitor metal layer.

11. The MIM capacitor structure of claim 8, wherein each of the at least one side of the fourth capacitor metal layer covers one side of the third capacitor metal layer.

12. The MIM capacitor structure of claim 11, wherein the fourth capacitor metal layer has a portion extending downward from a lower side of each of the at least one side of the fourth capacitor metal layer and facing the one side of the third capacitor metal layer adjacent thereto.

13. The MIM capacitor structure of claim 8, wherein the fourth capacitor metal layer covers all sides of the third capacitor metal layer.

14. The MIM capacitor structure of claim 8, further comprising:
a plurality of top metal layers spaced apart from each other above the fourth capacitor metal layer,
wherein each of the first, second, third, and fourth capacitor metal layers is electrically connected to each of the plurality of top metal layers by each contact.

15. A method of manufacturing a MIM capacitor structure of an image sensor, the method comprising:
depositing a first insulating film on a first metal layer, a second metal layer on the first insulating film, a second insulating film on the second metal layer, and a third metal layer on the second insulating film;
forming a first capacitor metal layer by etching the third metal layer;
depositing a third insulating film on the second insulating film to cover the first capacitor metal layer, and depositing a fourth metal layer on the third insulating film; and
forming a second capacitor metal layer on the third insulating film by etching the fourth metal layer,
wherein one side of the second capacitor metal layer is extending longer than a corresponding side of the first capacitor metal layer.

16. The method of claim 15, wherein the third insulating film has a step shape.

17. The method of claim 15, wherein the second capacitor metal layer is formed to cover one side of the first capacitor metal layer.

18. The method of claim 15, further comprising:
forming a first intermetallic insulating film, a second intermetallic insulating film, and a third capacitor metal layer by etching the second insulating film, the third insulating film, and the second metal layer.

19. The method of claim 18, further comprising:
forming a third intermetallic insulating film and a fourth capacitor metal layer by etching the first insulating film and the first metal layer.

20. The method of claim 19, wherein the fourth capacitor metal layer has a larger width than a width of the third capacitor metal layer.
